(19) United States
(12) Patent Application Publication
(10) Pub. No.: US 2008/0251842 A1
(43) Pub. Date: Oct. 16, 2008

(54) P-Channel FET Whose Hole Mobility is Improved by Applying Stress to the Channel Region and a Method of Manufacturing the Same

(76) Inventor: Gaku SUDO, Yokohama-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/043,453

(22) Filed: Mar. 7, 2008

(30) Foreign Application Priority Data
Mar. 7, 2007 (JP) 2007-057429

(51) Int. Cl. H01L 27/12; H01L 21/84

(52) U.S. Cl. 257/347; 438/151; 257/E27.112

(57) ABSTRACT

A p-channel FET which has a buried insulating film in the noncontact part of each of the source/drain regions has been disclosed. Compressional stress produced by volume expansion at the time of oxidization for the formation of the buried oxide films is applied to the channel region of the FET.

### CROSS-REFERENCE TO RELATED APPLICATIONS

This application is based upon and claims the benefit of priority from prior Japanese Patent Application No. 2007-057429, filed Mar. 7, 2007, the entire contents of which are incorporated herein by reference.

### BACKGROUND OF THE INVENTION

1. Field of the Invention

This invention relates to a semiconductor device using the technique for improving the hole mobility by applying stress to the channel region of the FET and a method of manufacturing the same, and more particularly to a p-channel FET and a method of manufacturing the same.

2. Description of the Related Art

In the field of semiconductor integrated circuit devices, in and after the 90-nm design rule generation, the technique for applying stress to the channel region of an FET to improve the electron or hole mobility to increase the drain current and therefore improve the performance has been under investigation.

To improve the performance of an n-channel FET, for example, a stress liner 101 for generating extensional stress is provided on a gate electrode, thereby applying extensional stress to the channel region 102A of FET Q1 and the channel region 102B of FET Q2 as shown by arrows A1, A2, B1, and B2 in FIG. 27. In this case, downward stress is also applied to the channel regions 102A and 102B as shown by arrows A3 and B3.

Furthermore, in a CMOS circuit, to apply optimum stress to each of an n-channel FET Q3 and a p-channel FET Q4, a stress liner 101 for generating extensional stress and a stress liner 103 for generating compressional stress, that is, two types of stress liners (DSL), are used as shown in FIG. 28 (e.g., refer to IEDM 2004 “Dual Stress Liner for High Performance sub-45-nm Gate Length SOI CMOS Manufacturing” H. S. Yang et al., pp. 1075-1078). Specifically, the stress liner 101 is provided on the gate electrode of the n-channel FET Q3, thereby applying extensional stress to the channel region 104 as shown by arrows A1 and A2. The stress liner 103 is provided on the gate electrode of the p-channel FET Q4, thereby applying compressional stress to the channel region 105 as shown by arrows C1 and C2.

In addition, a structure where an SiGe layer is used in place of a stress liner to apply stress to an n-channel FET has been proposed (e.g., refer to IEDM 2003 “A 90-nm High Volume Manufacturing Logic Technology Featuring Novel 45-nm Gate Length Strained Silicon CMOS Transistor” T. Ghani, et al., pp. 978-980). The technique for the Epitaxial SiGe (hereinafter, referred to as the eSiGe) is such that, for example, SiGe layers 106 and 107 are buried in the regions underlying the source/drain regions 108 and 109 of a p-channel FET Q4, respectively, as shown in FIG. 29, thereby applying compressional stress to the channel region 105 as shown by arrows C1 and C2 because of the difference in lattice parameter.

In the next generation, however, FETs are required to have much higher performance. As the generation becomes newer, FETs are miniaturized further, which makes it more difficult to form the stress liners 101, 103 serving as stress sources. Moreover, in the eSiGe technique using the difference in lattice parameter, high stress cannot be applied, which makes it impossible to produce a sufficient effect.

### BRIEF SUMMARY OF THE INVENTION

According to an embodiment of the invention, there is provided a semiconductor device comprising: an element isolating region formed at the main surface of a semiconductor substrate, a gate electrode provided via a gate insulating film above the semiconductor substrate in an element region partitioned by the element isolating region, a source/a drain region formed in the semiconductor substrate in the element region so as to sandwich the gate electrode between the source/drain regions, contact parts each connected to the top of each of the source/drain regions, and buried insulating films which are buried in the source/drain regions to apply stress to a channel region between the source/drain regions.

According to another embodiment of the invention, there is provided a semiconductor device comprising: an element isolating region formed in a silicon region of an SOI substrate, a gate electrode provided via a gate insulating film above an island-shaped silicon region partitioned by the element isolating region, a source/a drain region formed in the island-shaped silicon region so as to sandwich the gate electrode between the source/drain regions, contact parts each connected to the top of each of the source/drain regions, and buried insulating films which are buried in the source/drain regions to apply stress to a channel region between the source/drain regions.

According to still another embodiment of the invention, there is provided a semiconductor device manufacturing method comprising: forming an element isolating region at the main surface of a substrate, forming a gate insulating film and a gate electrode in an element region partitioned by the element isolating region, introducing impurities into the element region using the gate electrode as a part of a mask to form a source/a drain region, and forming buried insulating films in each of the source/drain regions to apply compressional stress to a channel region by volume expansion.

### BRIEF DESCRIPTION OF THE SEVERAL VIEWS OF THE DRAWING

FIG. 1A is a pattern plan view of a p-channel MOSFET to help explain a semiconductor device according to a first embodiment of the invention;

FIGS. 1B to 1D are sectional views taken along line 1B-1B, line 1C-1C, and 1D-1D, respectively, of the p-channel MOSFET of FIG. 1A to help explain the semiconductor device of the first embodiment;

FIG. 2A is a pattern plan view of a p-channel MOSFET to help explain a semiconductor device according to a second embodiment of the invention;

FIGS. 2B and 2C are sectional views taken along line 2B-2B and line 2C-2C, respectively, of the p-channel MOSFET of FIG. 2A to help explain the semiconductor device of the second embodiment;

FIG. 3 is a pattern plan view of a p-channel MOSFET to help explain a semiconductor device according to a third embodiment of the invention;

FIG. 4A is a pattern plan view of a p-channel MOSFET to help explain a semiconductor device according to a fourth embodiment of the invention;

FIGS. 4B and 4C are sectional views taken along line 4B-4B and line 4C-4C, respectively, of the p-channel MOSFET of FIG. 4A to help explain the semiconductor device of the fourth embodiment;

FIGS. 5A and 5B are sectional views of a p-channel MOSFET to help explain a semiconductor device according to a fifth embodiment of the invention;

FIGS. 6A and 6B are sectional views of a p-channel MOSFET to help explain a semiconductor device according to a sixth embodiment of the invention;

FIG. 7A is a pattern plan view of a p-channel MOSFET to help explain a first process in a semiconductor device manufacturing method according to a seventh embodiment of the invention;

FIG. 7B is a sectional view taken along line 7B-7B of the p-channel MOSFET of FIG. 7A to help explain the first process in the semiconductor device manufacturing method of the seventh embodiment;

FIG. 8A is a pattern plan view of the p-channel MOSFET to help explain a second process in the semiconductor device manufacturing method of the seventh embodiment;

FIG. 8B is a sectional view taken along line 8B-8B of the p-channel MOSFET of FIG. 8A to help explain the second process in the semiconductor device manufacturing method of the seventh embodiment;

FIG. 9A is a pattern plan view of the p-channel MOSFET to help explain a third process in the semiconductor device manufacturing method of the seventh embodiment;

FIG. 9B is a sectional view taken along line 9B-9B of the p-channel MOSFET of FIG. 9A to help explain the third process in the semiconductor device manufacturing method of the seventh embodiment;

FIG. 10A is a pattern plan view of the p-channel MOSFET to help explain a fourth process in the semiconductor device manufacturing method of the seventh embodiment;

FIG. 10B is a sectional view taken along line 10B-10B of the p-channel MOSFET of FIG. 10A to help explain the fourth process in the semiconductor device manufacturing method of the seventh embodiment;

FIG. 11A is a pattern plan view of the p-channel MOSFET to help explain a fifth process in the semiconductor device manufacturing method of the seventh embodiment;

FIG. 11B is a sectional view taken along line 11B-11B of the p-channel MOSFET of FIG. 11A to help explain the fifth process in the semiconductor device manufacturing method of the seventh embodiment;

FIG. 12A is a pattern plan view of a p-channel MOSFET to help explain a first process in a semiconductor device manufacturing method according to an eighth embodiment of the invention;

FIG. 12B is a sectional view taken along line 12B-12B of the p-channel MOSFET of FIG. 12A to help explain the first process in the semiconductor device manufacturing method of the eighth embodiment;

FIG. 13A is a pattern plan view of the p-channel MOSFET to help explain a second process in the semiconductor device manufacturing method of the eighth embodiment;

FIG. 13B is a sectional view taken along line 13B-13B of the p-channel MOSFET of FIG. 13A to help explain the second process in the semiconductor device manufacturing method of the eighth embodiment;

FIG. 14A is a pattern plan view of the p-channel MOSFET to help explain a third process in the semiconductor device manufacturing method of the eighth embodiment;

FIG. 14B is a sectional view taken along line 14B-14B of the p-channel MOSFET of FIG. 14A to help explain the third process in the semiconductor device manufacturing method of the eighth embodiment;

FIG. 15A is a pattern plan view of the p-channel MOSFET to help explain a fourth process in the semiconductor device manufacturing method of the eighth embodiment;

FIG. 15B is a sectional view taken along line 15B-15B of the p-channel MOSFET of FIG. 15A to help explain the fourth process in the semiconductor device manufacturing method of the eighth embodiment;

FIG. 16A is a pattern plan view of the p-channel MOSFET to help explain a fifth process in the semiconductor device manufacturing method of the eighth embodiment;

FIG. 16B is a sectional view taken along line 16B-16B of the p-channel MOSFET of FIG. 16A to help explain the fifth process in the semiconductor device manufacturing method of the eighth embodiment;

FIG. 17A is a pattern plan view of a p-channel MOSFET to help explain a first process in a semiconductor device manufacturing method according to a ninth embodiment of the invention;

FIG. 17B is a sectional view taken along line 17B-17B of the p-channel MOSFET of FIG. 17A to help explain the first process in the semiconductor device manufacturing method of the ninth embodiment;

FIG. 18A is a pattern plan view of the p-channel MOSFET to help explain a second process in the semiconductor device manufacturing method of the ninth embodiment;

FIG. 18B is a sectional view taken along line 18B-18B of the p-channel MOSFET of FIG. 18A to help explain the second process in the semiconductor device manufacturing method of the ninth embodiment;

FIG. 19A is a pattern plan view of the p-channel MOSFET to help explain a third process in the semiconductor device manufacturing method of the ninth embodiment;

FIG. 19B is a sectional view taken along line 19B-19B of the p-channel MOSFET of FIG. 19A to help explain the third process in the semiconductor device manufacturing method of the ninth embodiment;

FIG. 20A is a pattern plan view of the p-channel MOSFET to help explain a fourth process in the semiconductor device manufacturing method of the ninth embodiment;

FIG. 20B is a sectional view taken along line 20B-20B of the p-channel MOSFET of FIG. 20A to help explain the fourth process in the semiconductor device manufacturing method of the ninth embodiment;

FIG. 21A is a pattern plan view of the p-channel MOSFET to help explain a fifth process in the semiconductor device manufacturing method of the ninth embodiment;

FIG. 21B is a sectional view taken along line 21B-21B of the p-channel MOSFET of FIG. 21A to help explain the fifth process in the semiconductor device manufacturing method of the ninth embodiment;

FIG. 22A is a pattern plan view of a p-channel MOSFET to help explain a first process in a semiconductor device manufacturing method according to a tenth embodiment of the invention;

FIG. 22B is a sectional view taken along line 22B-22B of the p-channel MOSFET of FIG. 22A to help explain the first process in the semiconductor device manufacturing method of the tenth embodiment;

FIG. 23A is a pattern plan view of the p-channel MOSFET to help explain a second process in the semiconductor device manufacturing method of the tenth embodiment;

FIG. 23B is a sectional view taken along line 23B-23B of the p-channel MOSFET of FIG. 23A to help explain the second process in the semiconductor device manufacturing method of the tenth embodiment;

FIG. 24A is a pattern plan view of the p-channel MOSFET to help explain a third process in the semiconductor device manufacturing method of the tenth embodiment;

FIG. 24B is a sectional view taken along line 24B-24B of the p-channel MOSFET of FIG. 24A to help explain the third process in the semiconductor device manufacturing method of the tenth embodiment;

FIG. 25A is a pattern plan view of the p-channel MOSFET to help explain a fourth process in the semiconductor device manufacturing method of the tenth embodiment;

FIG. 25B is a sectional view taken along line 25B-25B of the p-channel MOSFET of FIG. 25A to help explain the fourth process in the semiconductor device manufacturing method of the tenth embodiment;

FIG. 26A is a pattern plan view of the p-channel MOSFET to help explain a fifth process in the semiconductor device manufacturing method of the tenth embodiment;

FIG. 26B is a sectional view taken along line 26B-26B of the p-channel MOSFET of FIG. 26A to help explain the fifth process in the semiconductor device manufacturing method of the tenth embodiment;

FIG. 27 is a sectional view of a first example to help explain a conventional semiconductor device and a method of manufacturing the semiconductor device;

FIG. 28 is a sectional view of a second example to help explain a conventional semiconductor device and a method of manufacturing the semiconductor device; and

FIG. 29 is a sectional view of a third example to help explain a conventional semiconductor device and a method of manufacturing the semiconductor device.

### DETAILED DESCRIPTION OF THE INVENTION

### First Embodiment

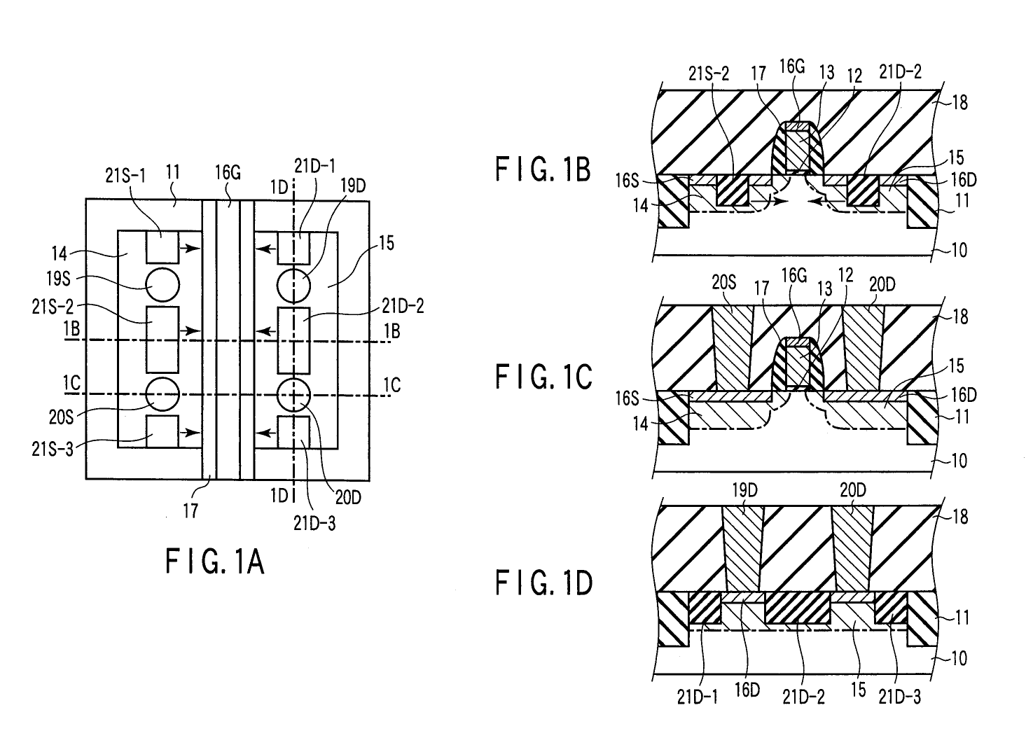

FIGS. 1A to 1D are diagrams of a p-channel MOSFET to help explain a semiconductor device according to a first embodiment of the invention. FIG. 1A is a pattern plan view of the p-channel MOSFET. FIG. 1B is a sectional view taken along line 1B-1B of FIG. 1A. FIG. 1C is a sectional view taken along line 1C-1C of FIG. 1A. FIG. 1D is a sectional view taken along line 1D-1D of FIG. 1A.

At the main surface of a semiconductor substrate (Si substrate) 10, an element isolating region (e.g., STI region) 11 for electrically separating element regions is formed. On the substrate 10 in an element region partitioned by the element isolating region 11, a gate oxide film (gate insulating film) 12 is formed. On the gate oxide film 12, a gate electrode 13 is formed. In the substrate 10, a source/a drain region 14, 15 are arranged so as to sandwich the gate electrode 13 between them. On the gate electrode 13 and source/drain regions 14, 15, silicide layers 16G, 16S, and 16D are formed, respectively.

On the sidewall of the gate electrode 13, an insulating film (oxide film or nitride film) is formed (in this case, explanation will be given using an oxide film as an example). On the main surface of the substrate 10, the insulating film 17, and the silicide layer 16G, an interlayer insulating film 18 is formed. In the position of the interlayer insulating film 18 corresponding to the source region 14, two contact parts 19S, 20S are formed. In the position of the interlayer insulating film 18 corresponding to the drain region 15, two contact parts 19D, 20D are formed. This produces a standard transistor configuration. Each of the contact parts 19S, 20S, 19D, 20D has its contact hole embedded with a metal plug, thereby electrically connecting to the silicide layers 16S, 16D.

In the region where the contact parts 19S, 20S, 19D, 20D have not been formed in the source/drain regions 14, 15, buried oxide films (buried insulating films) 21S-1, 21S-2, 21S-3, 21D-1, 21D-2, 21D-3 are arranged. These buried oxide films 21S-1, 21S-2, 21S-3, 21D-1, 21D-2, 21D-3 are not in contact with the element isolating region 11 in the channel length direction, but are in contact with the element isolating region 11 in the channel width direction (21S-1, 21S-3, 21D-1, 21D-3). Moreover, a cross section along line 1D-1D has a structure symmetric with respect to the center of the channel region as shown in FIG. 1D.

Although not shown, a wiring layer is formed on the interlayer insulating film 18. The contact parts 19S, 20S, 19D, 20D are connected electrically to a power supply, a ground point, and other elements, thereby configuring various circuits.

With the above configuration, when oxidizing is done to form the buried oxide films 21S-1, 21S-2, 21S-3, 21D-1, 21D-2, 21D-3, the oxide films expand in volume, applying compressional stress to the channel region of the p-channel MOSFET in the direction shown by the arrows, which improves the hole mobility and therefore increases the drain current. Since the buried oxide films 21S-1, 21S-2, 21S-3, 21D-1, 21D-2, 21D-3 are formed in the source/drain regions 14, 15 originally needed, a special space is not required. Moreover, since stress produced when the buried oxide films expand in volume is much higher than the one produced by the eSiGE technique using the difference in lattice parameter, a sufficiently great effect can be obtained even when miniaturization progresses further. Accordingly, stress can be applied to the channel region of the p-channel MOSFET to improve its performance.

### Second Embodiment

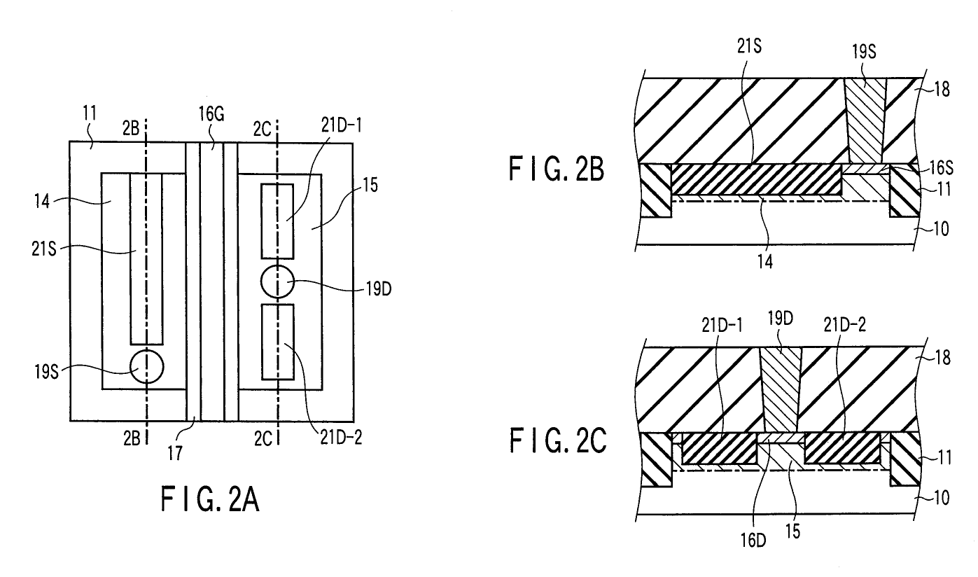

FIGS. 2A to 2C are diagrams of a p-channel MOSFET to help explain a semiconductor device according to a second embodiment of the invention. FIG. 2A is a pattern plan view of the p-channel MOSFET. FIG. 2B is a sectional view taken along line 2B-2B of FIG. 2A. FIG. 2C is a sectional view taken along line 2C-2C of FIG. 2A.

Although the basic structure of the FET is the same as that of the first embodiment, it has an asymmetric plane pattern. Specifically, the source/drain regions 14, 15 are provided with contact parts 19S, 19D, respectively. The contact part 19S is provided at the end of the source region 14. The contact part 19D is provided in the central part of the drain region 15. One end of the buried oxide film 21S is in contact with the element isolating region 11. Neither the buried oxide film 21D-1 nor the buried oxide film 21D-2 is in contact with the element isolating region 11.

As described above, even when the plane pattern of the FET is asymmetric, if compressional stress can be applied to the channel region, the hole mobility can be improved and therefore the drain current can be increased. Accordingly, this provides basically the same operational advantages as those of the first embodiment.

Whether the contact parts are located at the end of or in the central part of the source/drain regions 14, 15 or whether or not the buried oxide films are in contact with the element isolating region may be determined as needed.

### Third Embodiment

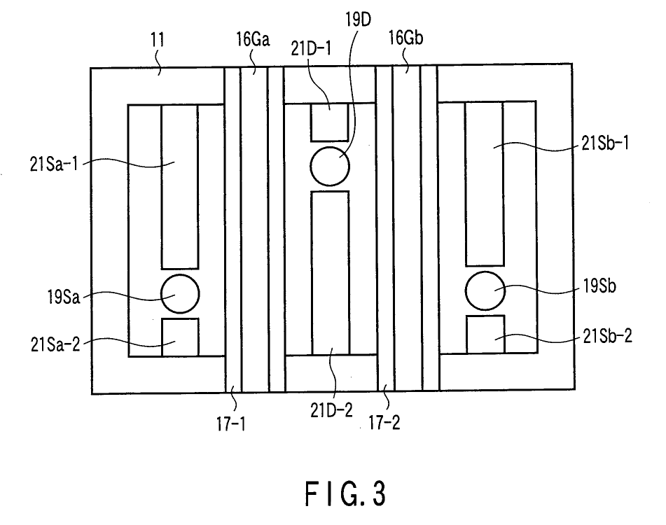

FIG. 3 is a pattern plan view of a p-channel MOSFET to help explain a semiconductor device according to a third embodiment of the invention. In the FET, two gate electrodes (silicide layers 16Ga, 16Gb in FIG. 3) are arranged in an element region. Two FETs share one of the source/drain regions (drain region in this case). Contact parts 19Sa, 19D, 19Sb are arranged alternately at one end and the other end of the source/drain regions. Moreover, buried oxide films 21Sa-1, 21Sa-2 are arranged so as to sandwich the contact part 19Sa between them. Buried oxide films 21D-1, 21D-2 are arranged so as to sandwich the contact part 19D between them. Buried oxide films 21Sb-1, 21Sb-2 are arranged so as to sandwich the contact part 19Sb between them. One end of each of the buried oxide films 21Sa-1, 21Sa-2, 21D-1, 21D-2, 21Sb-1, 21Sb-2 is in contact with the element isolating region 11.

The remaining configuration is the same as that of each of the first and second embodiments.

As described above, even if the pattern configuration is such that two FETs share one of the source/drain regions, compressional stress can be applied to the channel region of an adjacent FET using volume expansion at the time of the formation of the buried oxide films 21Sa-1, 21Sa-2, 21D-1, 21D-2, 21Sb-1, 21Sb-2. As a result, the drain current of the FET can be increased by improving the hole mobility. Accordingly, the performance of the FET is improved, which provides basically the same operational advantages as those of the first and second embodiments.

### Fourth Embodiment

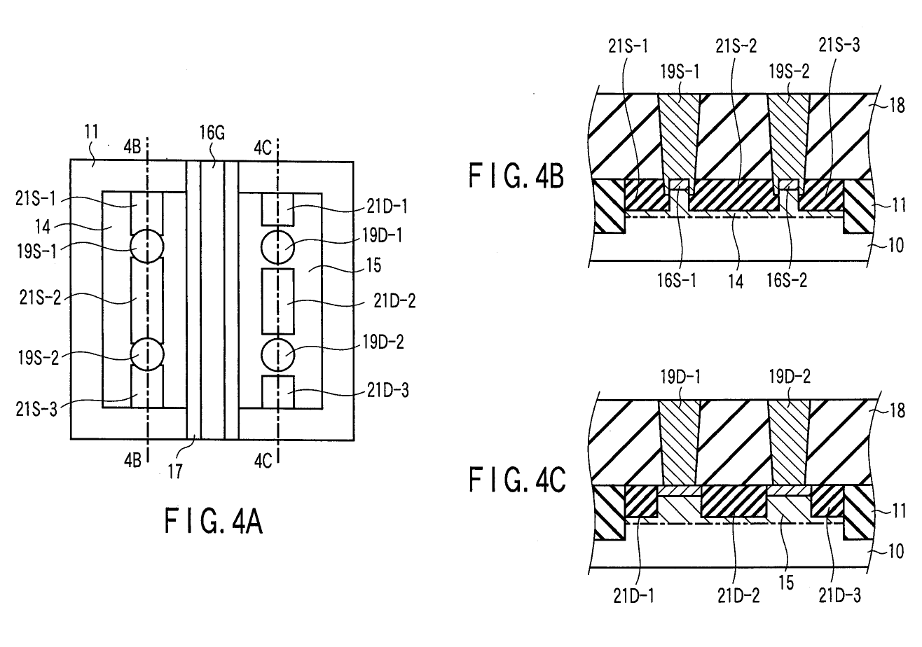

FIGS. 4A to 4C are diagrams of a p-channel MOSFET to help explain a semiconductor device according to a fourth embodiment of the invention. FIG. 4A is a pattern plan view of the p-channel MOSFET. FIG. 4B is a sectional view taken along line 4B-4B of FIG. 4A. FIG. 4C is a sectional view taken along line 4C-4C of FIG. 4A.

Although the basic structure of the FET is the same as that of the first embodiment, a contact part 19S-1 overlaps with part of buried oxide films 21S-1, 21S-2 and a contact part 19S-2 overlaps with part of buried oxide films 21S-2, 21S-3. This configuration can be obtained by digging in the end of each of the buried oxide films 21S-1, 21S-2, 21S-3 when contact holes are made in the interlayer insulating film 18.

With this configuration, in addition to the effects of the first to third embodiments, the width of each of the buried oxide films 21S-1, 21S-2, 21S-3 can be made greater without increasing the pattern occupied area of the element region. Consequently, the contact area between the contact parts 19S-1, 19S-2 and the silicide layers 16S-1, 16S-2 can be made larger.

Accordingly, even when miniaturization progresses further, a sufficiently great effect can be obtained and stress can be applied effectively to the channel region of a FET, improving its performance.

In the fourth embodiment, the pattern configuration is such that the contact part 19S-1 on the source side overlaps with part of the buried oxide films 21S-1, 21S-2 and the contact part 19S-2 on the source side overlaps with part of the buried oxide films 21S-2, 21S-3. The same operational advantages can be obtained even with a pattern configuration where the contact part 19D-1 on the drain side overlaps with part of the buried oxide films 21D-1, 21D-2 and the contact part 19D-2 on the drain side overlaps with part of the buried oxide films 21D-2, 21D-3. A pattern configuration may be such that the contact parts on both of the source and drain sides overlap with part of the buried oxide films.

### Fifth Embodiment

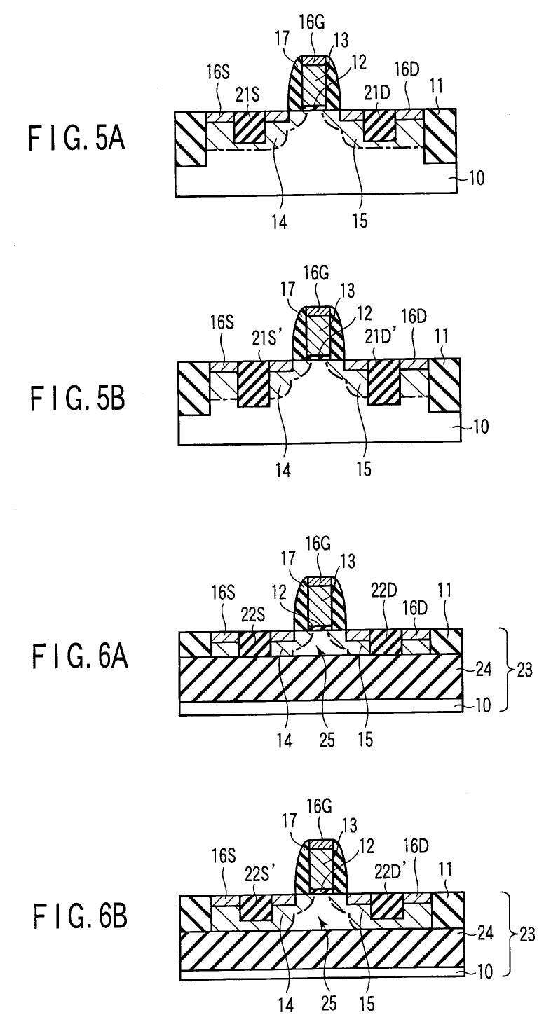

FIGS. 5A and 5B are sectional views to help explain a semiconductor device according to a fifth embodiment of the invention. In the first to fourth embodiments, the explanation has been given using a case where the buried oxide films 21S, 21D are shallower than the junction of the source/drain regions 14, 15 as shown in FIG. 5A.

However, as shown in FIG. 5B, buried oxide films 21S′, 21D′ may be formed so as to be deeper than the junction of the source/drain regions 14, 15. The buried oxide films 21S, 21D may be shallower than the junction of the source/drain regions as shown in FIG. 5A or deeper than the junction as shown in FIG. 5B, provided that compressional stress is applied to the channel region as a result of volume expansion at the time of oxidization.

### Sixth Embodiment

FIGS. 6A and 6B are sectional views to help explain a semiconductor device according to a sixth embodiment of the invention. FIGS. 6A and 6B show an example of forming a p-channel MOSFET in a silicon-on-insulator (SOI) wafer (SOI substrate). In an SOI substrate 23, a buried oxide (BOX) layer 24 is formed on a semiconductor substrate 10. On the BOX layer 24, a silicon layer is formed. In the silicon layer 23, an element isolating region 11 is formed until it reaches the depth of the BOX layer 24, thereby forming an island-shaped silicon region 25 serving as an element region.

Above the silicon region 25, a gate electrode 13 is formed via a gate oxide film 12. On the gate electrode 13, a silicide layer 16G is formed. On the sidewall of the gate electrode 13, an insulating film 17 is formed. Source/drain regions 14, 15 are formed in the silicon region 25 so as to sandwich the gate electrode 13 between them. On the source/drain regions 14, 15, silicide layers 16S, 16D are formed, respectively.

In the source/drain regions 14, 15, buried insulating films 22S, 22D for applying compressional stress to the channel region are formed, respectively. The configuration of FIG. 6A shows a case where the buried oxide films 22S, 22D have reached the BOX layer 24. The configuration of FIG. 6B shows a case where the buried oxide films 22S′, 22D′ have not reached the BOX layer 24.

When the invention is applied to an SOI wafer, the buried oxide films may reach the BOX layer 24 as shown in FIG. 6A or may not reach the BOX layer as shown in FIG. 6B, provided that compressional stress is applied to the channel region.

Even with the above configuration, compressional stress can be applied to the channel region by volume expansion at the time of the formation of the buried oxide films 21S, 21D, which enables the hole mobility to be improved and therefore the drain current to be increased. Since the buried oxide films 21S, 21D are formed in the source/drain regions 14, 15 originally needed in the FET, a special space is not required. Moreover, since compressional stress is much higher than the one produced by the eSiGE technique, a sufficiently great effect can be obtained even when miniaturization progresses further. Accordingly, stress can be applied effectively to the channel region of the FET to improve its performance.

### Seventh Embodiment

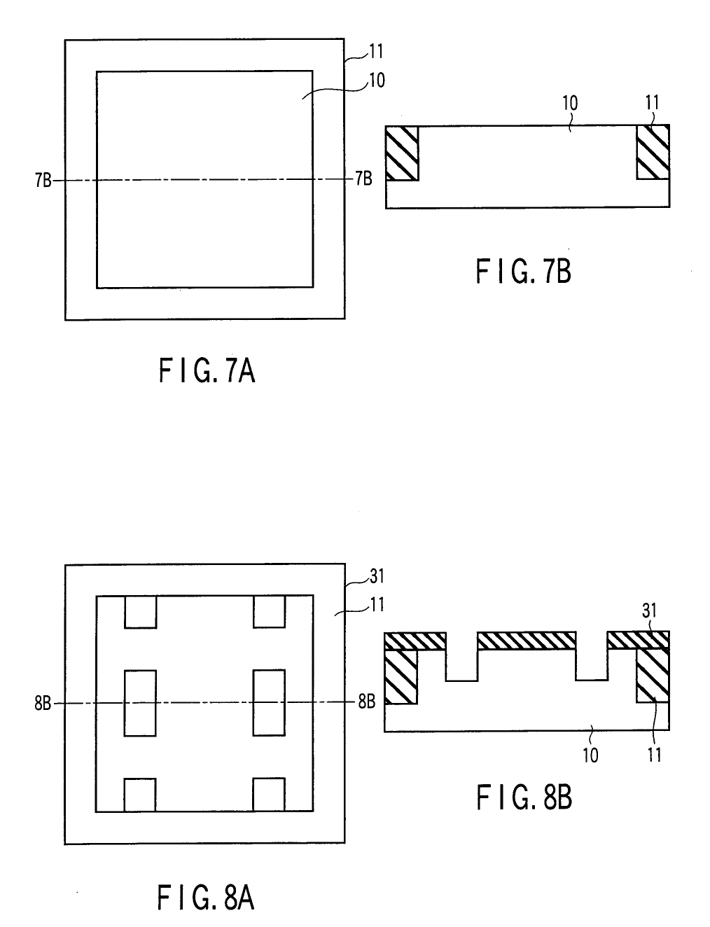

FIGS. 7A and 7B to FIGS. 11A and 11B are diagrams to help explain a semiconductor device manufacturing method according to a seventh embodiment of the invention. Part of the manufacturing processes of the p-channel MOSFET shown in FIGS. 1A to 1D are shown in sequence. FIGS. 7A, 8A, 9A, 10A, and 11A are pattern plan views of the p-channel MOSFET. FIGS. 7B, 8B, 9B, 10B, and 11B are sectional views of FIGS. 7A, 8A, 9A, 10A, and 11A, respectively.

First, as shown in FIGS. 7A and 7B, at the main surface of a semiconductor substrate 10, an element isolating region 11 is formed. The explanation is given using an STI structure as an example. A region partitioned by the element isolating region 11 is an element region.

Next, as shown in FIGS. 8A and 8B, a film of a hard mask 31 for forming a buried oxide film is formed on the substrate. The film is patterned using photoresist. Then, the places of the substrate 10 corresponding to the hard mask 31 are recessed.

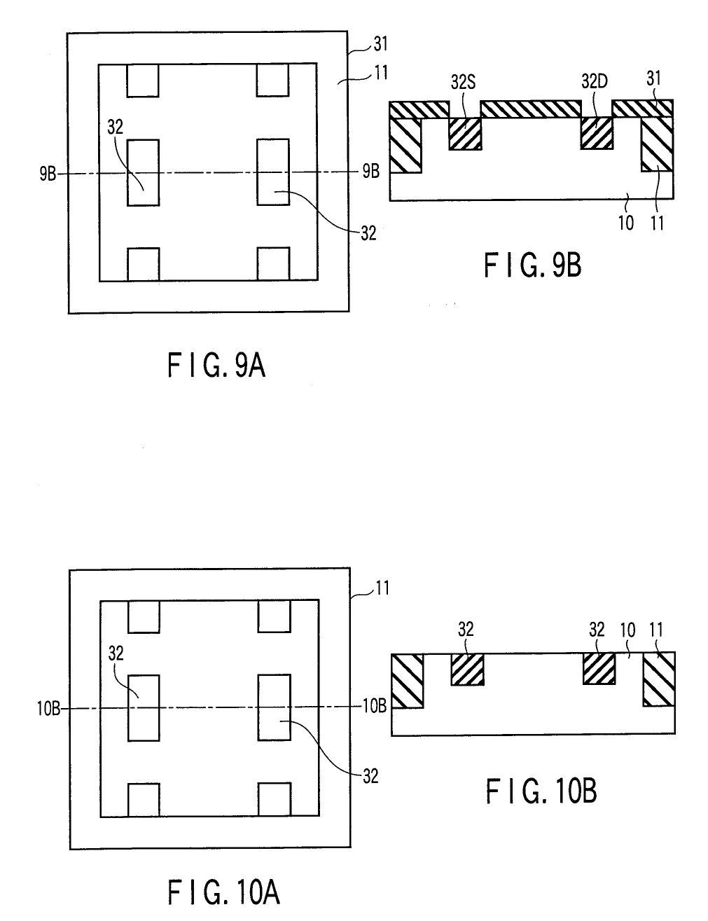

Thereafter, an oxide film is formed on the hard mask 31 and in the recessed substrate 10. Then, using CMP and wet etching techniques or only wet etching techniques, the oxide film is caused to remain in the recessed places of the substrate 10 as shown in FIGS. 9A and 9B, thereby forming buried oxide films 32S, 32D.

Next, as shown in FIGS. 10A and 10B, the hard mask 31 is removed.

Hereafter, using well-known manufacturing techniques, a gate oxide film 12, a gate electrode 13, a sidewall insulating film 17, and others are formed as shown in FIGS. 11A and 11B. As an example, the surface of the element region partitioned by the element isolating region 11 is thermally oxidized, thereby forming a gate oxide film. On the gate oxide film, a gate electrode material layer, such as a polysilicon layer, is formed and patterned, thereby forming a gate oxide film 12 and a gate electrode 13. Then, after an oxide film is formed on the entire surface by CVD techniques or the like, etching back is done, thereby causing the oxide film to remain on the sidewall of the gate electrode 13. Moreover, using the gate electrode 13 as a part of the mask, impurities are introduced into the substrate 10, thereby forming source/drain regions 14, 15. Then, by a salicide process, a silicide layer (not shown) is formed on the gate electrode 13 and source/drain regions 14, 15. Moreover, after an interlayer insulating film is formed on the entire surface, contact holes are made in the corresponding positions above the source/drain regions 14, 15. Then, metal plugs are fitted in the holes, thereby forming contact parts. Then, on the interlayer insulating film, a wiring layer is formed and then a surface protective film is formed.

With the aforementioned manufacturing method, compressional stress can be applied to the channel region of the p-channel MOSFET by volume expansion at the time of the formation of the buried oxide films 32S, 32D. This enables the hole mobility to be improved and therefore the drain current to be increased. Since the buried oxide films 32S, 32D are formed in the source/drain regions 14, 15, a special space is not required and, even when the FET is miniaturized further, a great effect can be obtained.

### Eighth Embodiment

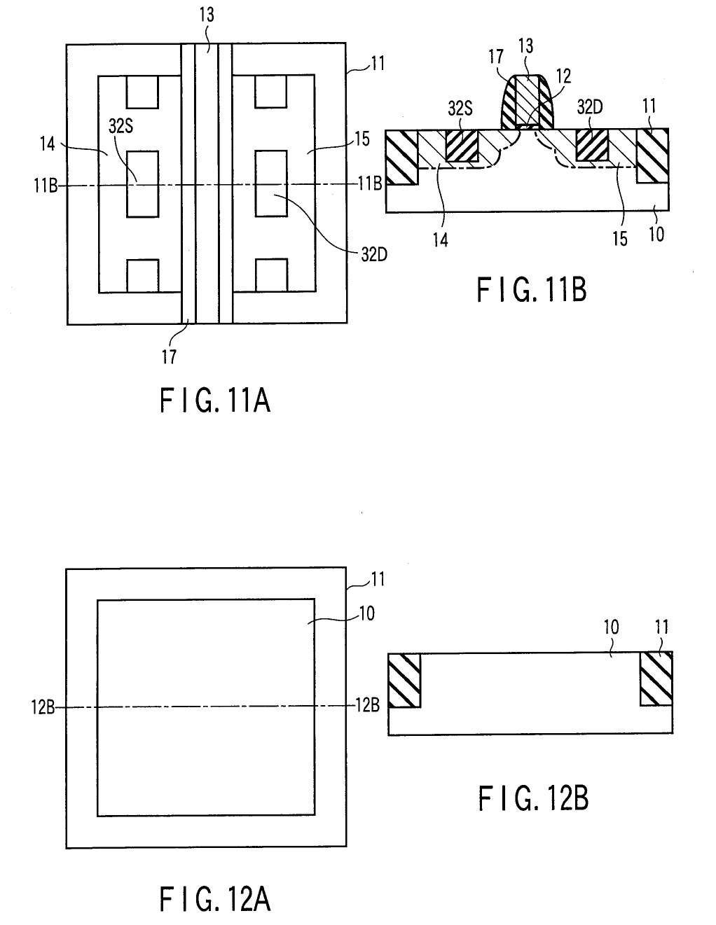

FIGS. 12A and 12B to FIGS. 16A and 16B are diagrams to help explain a semiconductor device manufacturing method according to an eighth embodiment of the invention. Part of the manufacturing processes of a p-channel MOSFET are shown in sequence. FIGS. 12A, 13A, 14A, 15A, and 16A are pattern plan views of the p-channel MOSFET. FIGS. 12B, 13B, 14B, 15B, and 16B are sectional views of FIGS. 12A, 13A, 14A, 15A, and 16A, respectively.

First, as shown in FIGS. 12A and 12B, at the main surface of a semiconductor substrate 10, an element isolating region 11 is formed. The explanation is given using an STI structure as an example. A region partitioned by the element isolating region 11 is an element region.

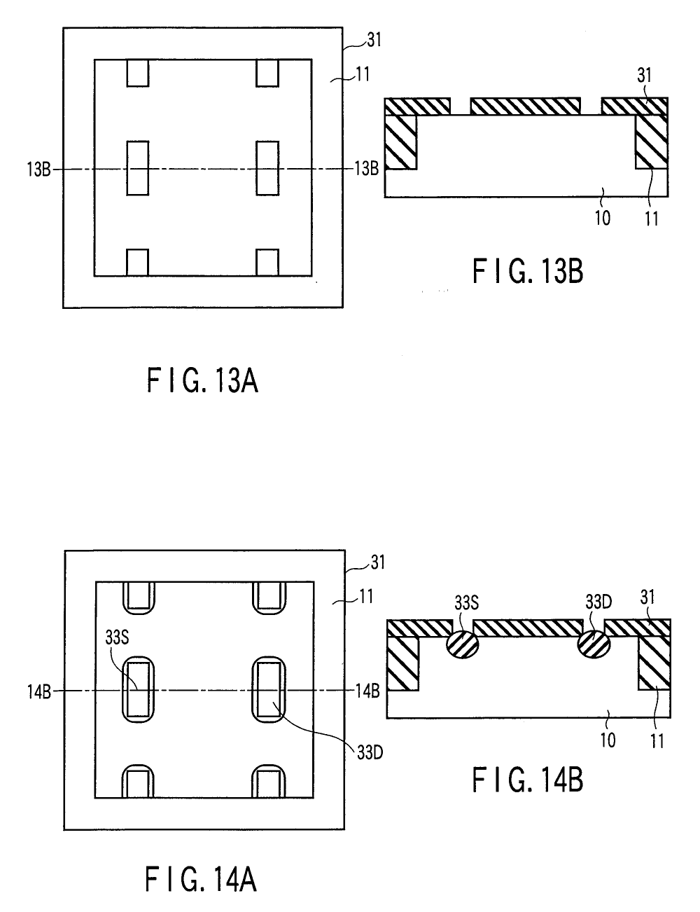

Next, as shown in FIGS. 13A and 13B, a film of a hard mask 31 for forming a buried oxide film is formed on the substrate 10. The film is patterned using photoresist.

Thereafter, the substrate 10 exposed in the openings in the hard mask 31 is oxidized, thereby forming oxide films (buried oxide films) 33S, 33D.

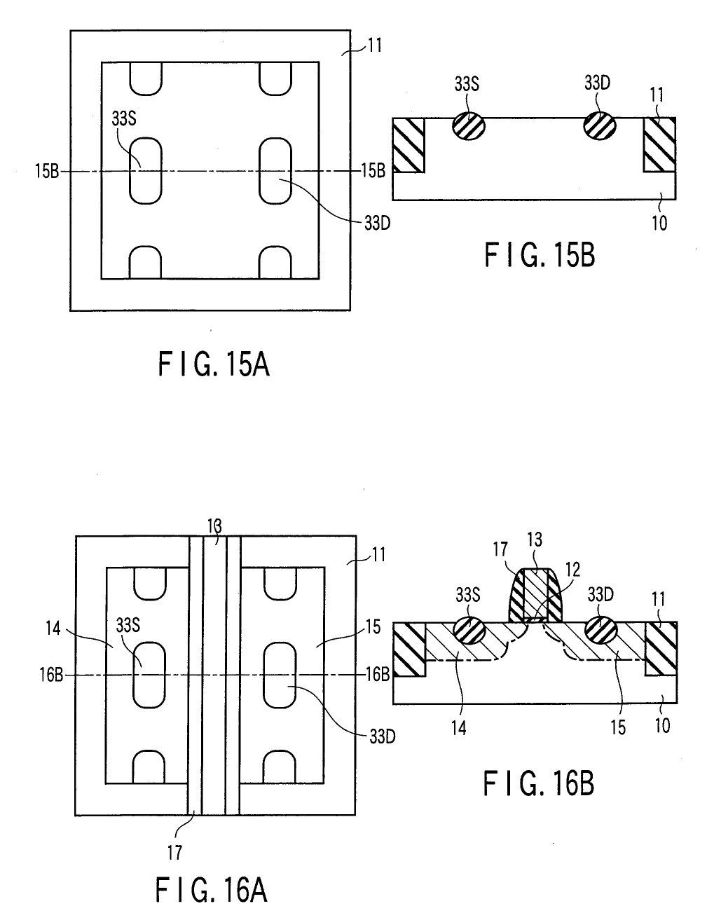

Next, as shown in FIGS. 15A and 15B, the hard mask 31 is removed.

Hereafter, using well-known manufacturing techniques, a gate oxide film 12, a gate electrode 13, a sidewall insulating film 17, and others are formed as shown in FIGS. 16A and 16B. As an example, the surface of the element region partitioned by the element isolating region 11 is thermally oxidized, thereby forming a gate oxide film. On the gate oxide film, a gate electrode material layer, such as a polysilicon layer, is formed and patterned, thereby forming a gate oxide film 12 and a gate electrode 13. Then, after an oxide film is formed on the entire surface by CVD techniques or the like, etching back is done, thereby causing the oxide film to remain on the sidewall of the gate electrode 13. Moreover, using the gate electrode 13 as a part of the mask as in the seventh embodiment, impurities are introduced into the substrate 10, thereby forming source/drain regions 14, 15. Then, by a salicide process, a silicide layer (not shown) is formed on the gate electrode 13 and source/drain regions 14, 15. Moreover, after an interlayer insulating film is formed on the entire surface, contact holes are made in the corresponding positions above the source/drain regions 14, 15. Then, metal plugs are fitted in the holes, thereby forming contact parts. Then, on the interlayer insulating film, a wiring layer is formed and then a surface protective film is formed.

With the aforementioned manufacturing method, compressional stress can be applied to the channel region of the p-channel MOSFET by volume expansion at the time of the formation of the buried oxide films 33S, 33D. This enables the hole mobility to be improved and therefore the drain current to be increased. Since the buried oxide films 33S, 33D are formed in the source/drain regions 14, 15, a special space is not required and, even when the FET is miniaturized further, a great effect can be obtained.

### Ninth Embodiment

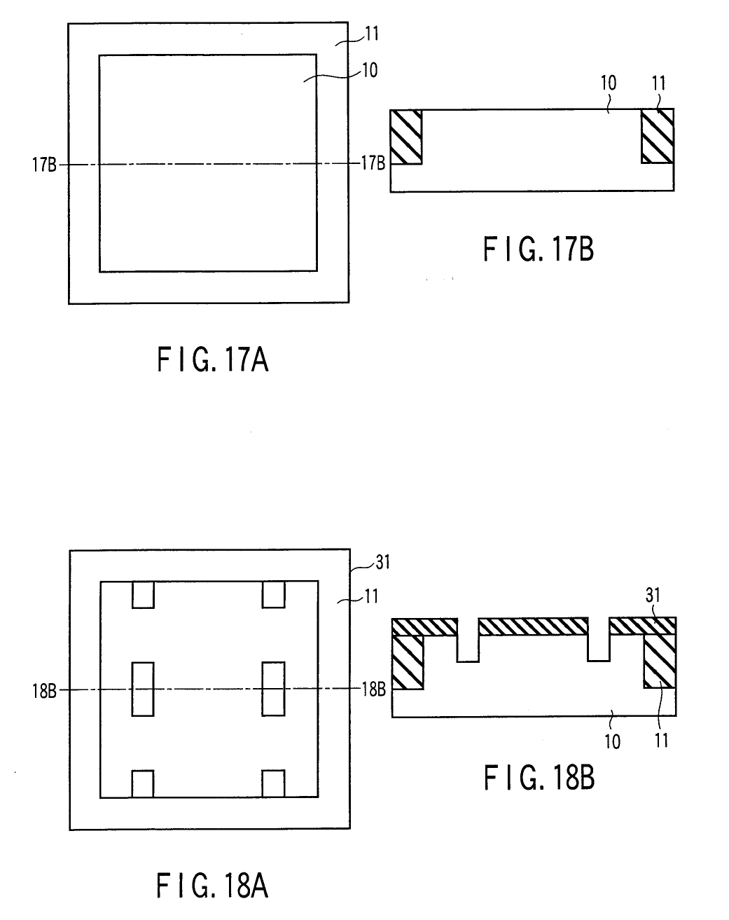

FIGS. 17A and 17B to FIGS. 21A and 21B are diagrams to help explain a semiconductor device manufacturing method according to a ninth embodiment of the invention. Part of the manufacturing processes of the p-channel MOSFET shown in FIGS. 1A to 1D are shown in sequence. FIGS. 17A, 18A, 19A, 20A, and 21A are pattern plan views of the p-channel MOSFET. FIGS. 17B, 18B, 19B, 20B, and 21B are sectional views of FIGS. 17A, 18A, 19A, 20A, and 21A, respectively.

First, as shown in FIGS. 17A and 17B, at the main surface of a semiconductor substrate 10, an element isolating region 11 is formed. The explanation is given using an STI structure as an example. A region partitioned by the element isolating region 11 is an element region.

Next, as shown in FIGS. 18A and 18B, a film of a hard mask 31 for forming a buried oxide film is formed on the substrate 10. The film is patterned using photoresist. Then, the places of the substrate 10 corresponding to the hard mask 31 are recessed.

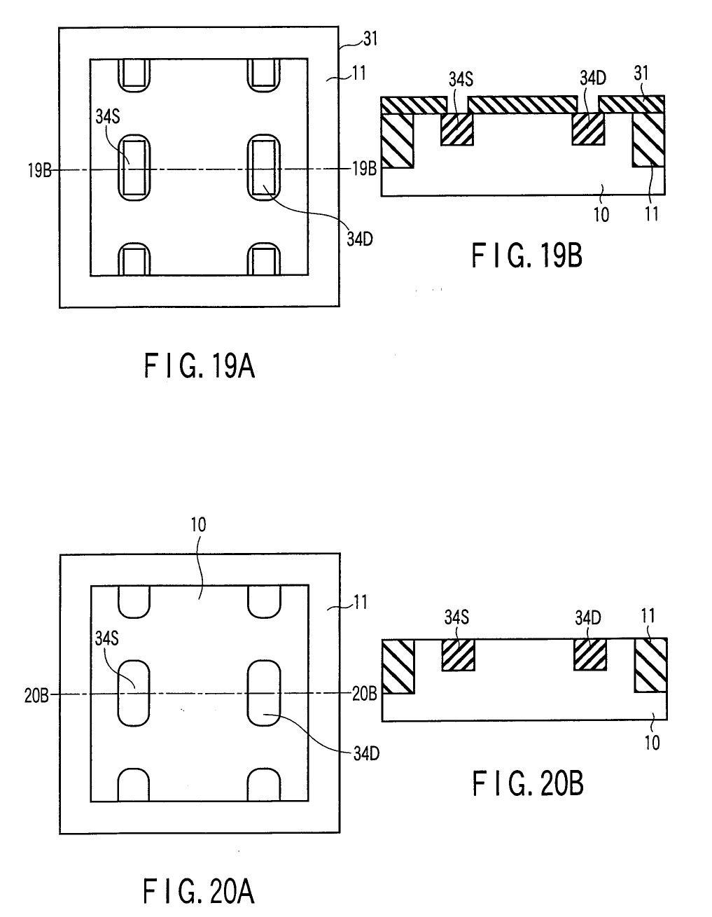

Thereafter, as shown in FIGS. 19A and 19B, the surface of the recessed substrate 10 is oxidized, thereby forming oxide films (buried oxide films) 34S, 34D.

Next, as shown in FIGS. 20A and 20B, the hard mask 31 is removed.

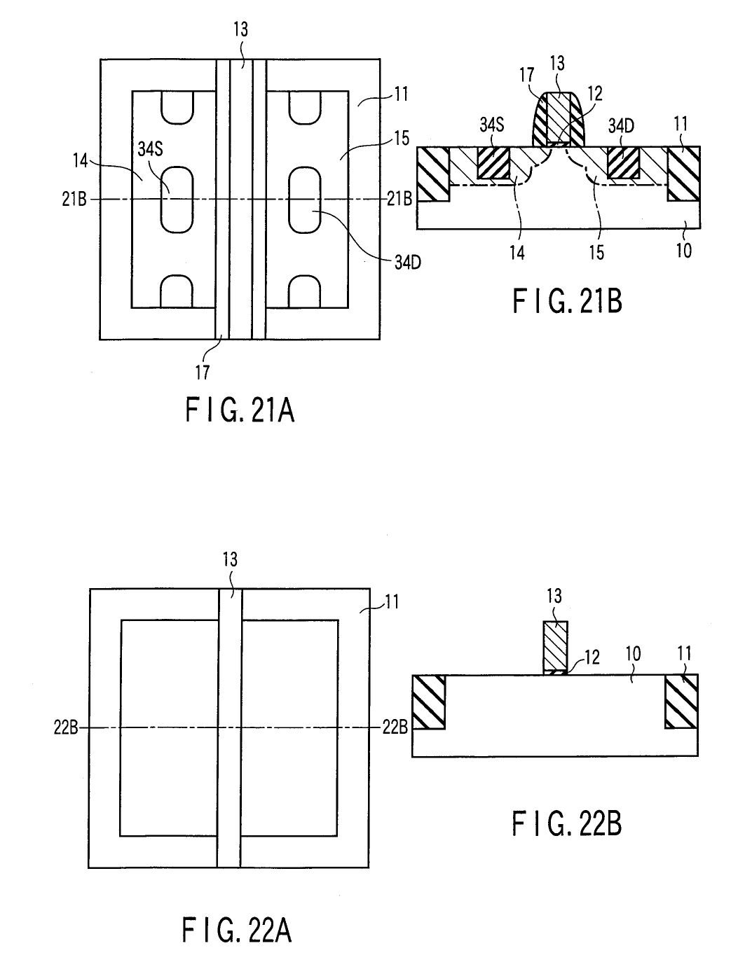

Hereafter, using well-known manufacturing techniques, a gate oxide film 12, a gate electrode 13, a sidewall insulating film 17, and others are formed as shown in FIGS. 21A and 21B. As an example, the surface of the element region partitioned by the element isolating region 11 is thermally oxidized, thereby forming a gate oxide film. On the gate oxide film, a gate electrode material layer, such as a polysilicon layer, is formed and patterned, thereby forming a gate oxide film 12 and a gate electrode 13. Then, after an oxide film is formed on the entire surface by CVD techniques or the like, etching back is done, thereby causing the oxide film to remain on the sidewall of the gate electrode 13. Moreover, using the gate electrode 13 as a part of the mask as in the seventh and eighth embodiments, impurities are introduced into the substrate 10, thereby forming source/drain regions 14, 15. Then, by a salicide process, a silicide layer (not shown) is formed on the gate electrode 13 and source/drain regions 14, 15. Moreover, after an interlayer insulating film is formed on the entire surface, contact holes are made in the corresponding positions above the source/drain regions. Then, metal plugs are fitted in the holes, thereby forming contact parts. Then, on the interlayer insulating film, a wiring layer is formed and then a surface protective film is formed.

With the aforementioned manufacturing method, compressional stress can be applied to the channel region of the p-channel MOSFET by volume expansion at the time of the formation of the buried oxide films 34S, 34D. This enables the hole mobility to be improved and therefore the drain current to be increased. Since the buried oxide films 34S, 34D are formed in the source/drain regions 14, 15, a special space is not required and, even when the FET is miniaturized further, a great effect can be obtained.

### Tenth Embodiment

FIGS. 22A and 22B to FIGS. 26A and 26B are diagrams to help explain a semiconductor device manufacturing method according to a tenth embodiment of the invention. Part of the manufacturing processes of the p-channel MOSFET shown in FIGS. 1A to 1D are shown in sequence. FIGS. 22A, 23A, 24A, 25A, and 26A are pattern plan views of the p-channel MOSFET. FIGS. 22B, 23B, 24B, 25B, and 26B are sectional views of FIGS. 22A, 23A, 24A, 25A, and 26A, respectively.

First, as shown in FIGS. 22A and 22B, at the main surface of a semiconductor substrate 10, an element isolating region 11 is formed. The explanation is given using an STI structure as an example. A region partitioned by the element isolating region 11 is an element region. The surface of the element region partitioned by the element isolating region 11 is thermally oxidized, thereby forming a gate oxide film. On the gate oxide film, a gate electrode material layer, such as a polysilicon layer, is formed and patterned, thereby forming a gate oxide film 12 and a gate electrode 13.

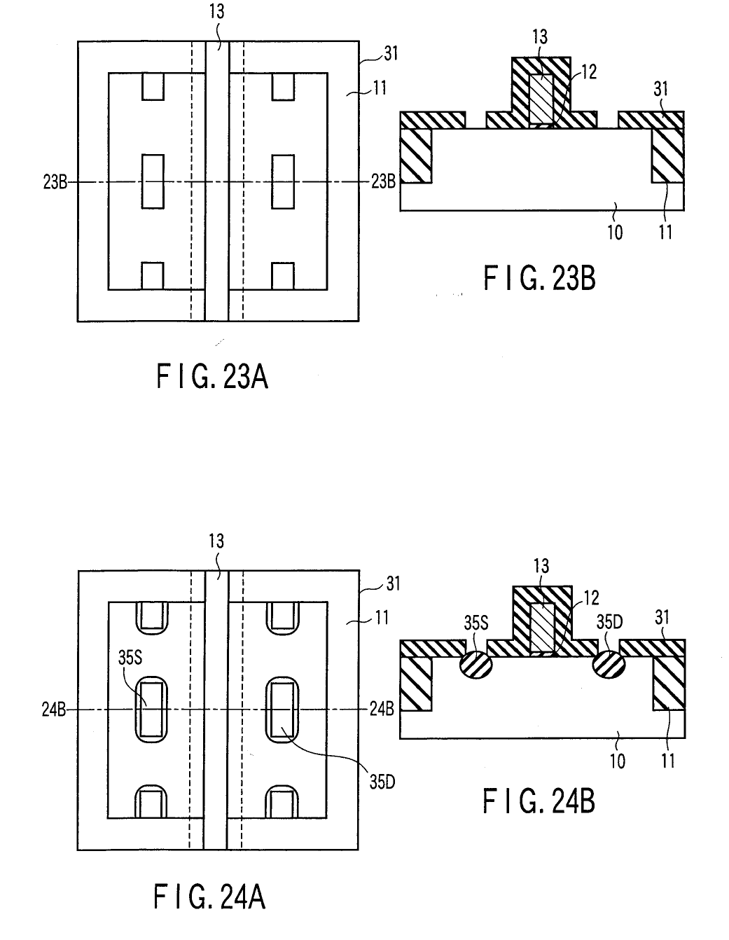

Next, as shown in FIGS. 23A and 23B, a film of a hard mask 31 for forming a buried oxide film is formed on the substrate 10 and the gate electrode 13 and on the sidewall of the gate electrode 13. The film is patterned using photoresist, thereby removing a desired place of the hard mask 31.

Then, as shown in FIGS. 24A and 24B, the surface of the substrate 10 in the openings in the hard mask 31 is oxidized, thereby forming oxide films 35S, 35D.

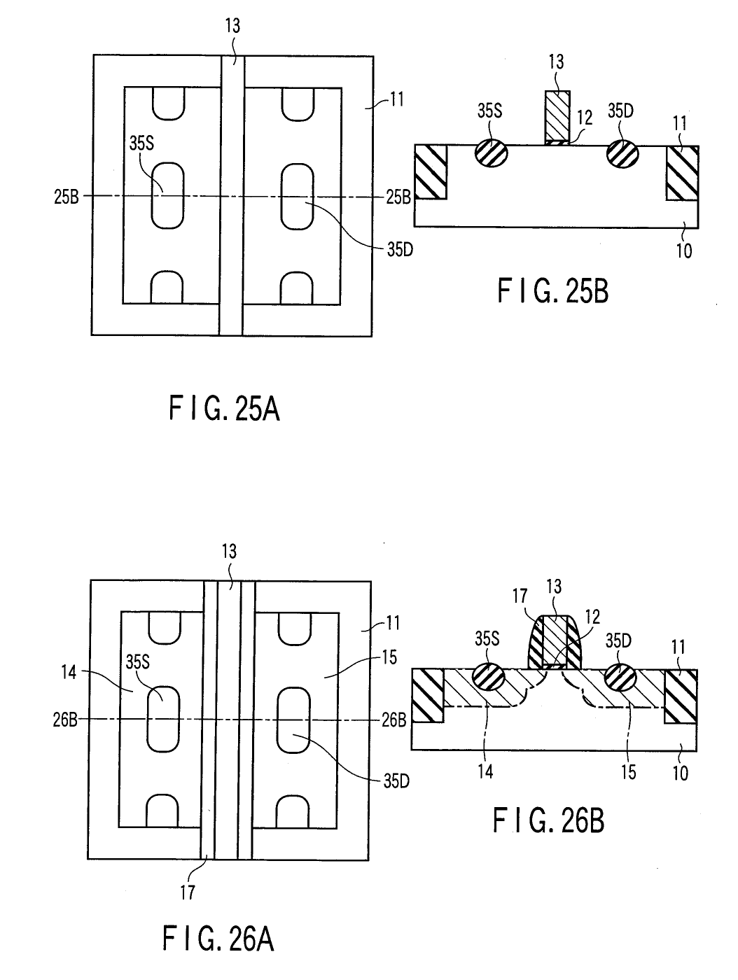

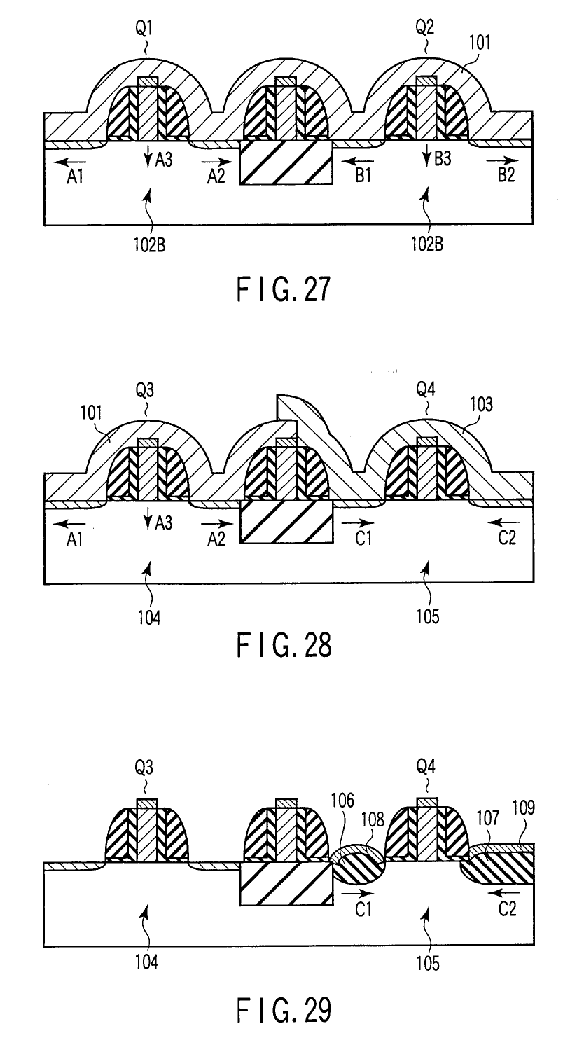

Thereafter, as shown in FIGS. 25A and 25B, the hard mask 31 is removed.

Hereafter, using well-known techniques, an insulating film 17 is formed on the gate electrode 13 as shown in FIGS. 26A and 26B. Moreover, using the gate electrode 13 as a part of the mask, impurities are introduced into the substrate 10, thereby forming source/drain regions 14, 15. Then, by a salicide process, a silicide layer (not shown) is formed on the gate electrode 13 and source/drain regions 14, 15. Moreover, after an interlayer insulating film is formed on the entire surface, contact holes are made in the corresponding positions above the source/drain regions. Then, metal plugs are fitted in the holes, thereby forming contact parts. Then, on the interlayer insulating film, a wiring layer is formed and then a surface protective film is formed.

With the aforementioned manufacturing method, compressional stress can be applied to the channel region of the p-channel MOSFET by volume expansion at the time of the formation of the oxide films 35S, 35D. This enables the hole mobility to be improved and therefore the drain current to be increased. Since the buried oxide films 35S, 35D are formed in the source/drain regions 14, 15, a special space is not required and, even when the FET is miniaturized further, a great effect can be obtained.

As described above, a semiconductor device according to an embodiment of the invention comprises an element isolating region formed at the main surface of a semiconductor substrate, a gate electrode provided via a gate insulating film above the semiconductor substrate in an element region partitioned by the element isolating region, a source/a drain region formed so as to sandwich the gate electrode between the source/drain regions, contact parts each connected to the top of each of the source/drain regions, and buried insulating films which are buried in the source/drain regions to apply stress to a channel region between the source/drain regions.

The semiconductor device has a configuration as described in item (a) to item (h) below:

(a) The buried insulating films are provided in the noncontact part of the source/drain regions.

(b) The contact holes are formed so as to partially overlap with the top of the buried insulating films.

(c) The buried insulating films are oxide films.

(d) The buried insulating films are shallower or deeper than the element isolating region.

(e) The buried insulating films are shallower or deeper than the junction of the source/drain regions.

(f) The depth of the buried insulating films is two or more times that of the gate insulating film.

(g) The buried insulating films make no contact with the element isolating region.

(h) The buried insulating films make contact with the element isolating region in the channel width direction, but make no contact with the element isolating region in the channel length direction.

Furthermore, a semiconductor device according to another embodiment of the invention comprises an element isolating region formed in a silicon region of an SOI substrate, a gate electrode provided via a gate insulating film above an island-shaped silicon region partitioned by the element isolating region, a source/a drain region formed so as to sandwich the gate electrode between the source/drain regions, contact parts each connected to the top of each of the source/drain regions, and buried insulating films which are buried in the source/drain regions to apply stress to a channel region between the source/drain regions.

The semiconductor device has a configuration as described in item (i) to item (o) below:

(i) The buried insulating films are provided in the noncontact part of the source/drain regions.

(j) The contact holes are formed so as to partially overlap with the top of the buried insulating films.

(k) The buried insulating films are oxide films.

(l) The buried insulating films have reached the BOX layer.

(m) The depth of the buried insulating films is two or more times that of the gate insulating film.

(n) The buried insulating films make no contact with the element isolating region.

(o) The buried insulating films make contact with the element isolating region in the channel width direction, but make no contact with the element isolating region in the channel length direction.

In addition, a semiconductor device manufacturing method according to still another embodiment of the invention comprises forming an element isolating region at the main surface of a semiconductor substrate, forming a gate insulating film and a gate electrode in an element region partitioned by the element isolating region, introducing impurities into the element region using the gate electrode as a part of a mask to form a source/a drain region, and forming buried insulating films in each of the source/drain regions to apply compressional stress to a channel region by volume expansion.

As described above, according to one aspect of the invention, there are provided a semiconductor device capable of applying stress effectively to the channel region of an FET and a method of manufacturing the semiconductor device.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor device comprising:
an element isolating region formed at the main surface of a semiconductor substrate;
a gate electrode provided via a gate insulating film above the semiconductor substrate in an element region partitioned by the element isolating region;
a source/a drain region formed in the semiconductor substrate in the element region so as to sandwich the gate electrode between the source/drain regions;
contact parts each connected to the top of each of the source/drain regions; and
buried insulating films which are buried in the source/drain regions to apply stress to a channel region between the source/drain regions.

2. The semiconductor device according to claim 1, wherein the buried insulating films are oxide films which apply compressional stress to the channel region between the source/drain regions by volume expansion.

3. The semiconductor device according to claim 1, wherein the buried insulating films are provided in the noncontact part of the source/drain regions.

4. The semiconductor device according to claim 1, wherein contact holes are formed so as to partially overlap with the top of the buried insulating films.

5. The semiconductor device according to claim 1, wherein the buried insulating films are shallower or deeper than the element isolating region.

6. The semiconductor device according to claim 1, wherein the buried insulating films are shallower or deeper than the junction of the source/drain regions.

7. The semiconductor device according to claim 1, wherein the depth of the buried insulating films is two or more times that of the gate insulating film.

8. The semiconductor device according to claim 1, wherein the buried insulating films make no contact with the element isolating region.

9. The semiconductor device according to claim 1, wherein the buried insulating films make contact with the element isolating region in the channel width direction, but make no contact with the element isolating region in the channel length direction.

10. A semiconductor device comprising:
an element isolating region formed in a silicon region of an SOI substrate;
a gate electrode provided via a gate insulating film above an island-shaped silicon region partitioned by the element isolating region;
a source/a drain region formed in the island-shaped silicon region so as to sandwich the gate electrode between the source/drain regions;
contact parts each connected to the top of each of the source/drain regions; and
buried insulating films which are buried in the source/drain regions to apply stress to a channel region between the source/drain regions.

11. The semiconductor device according to claim 10, wherein the buried insulating films are oxide films which apply compressional stress to the channel region between the source/drain regions by volume expansion.

12. The semiconductor device according to claim 10, wherein the buried insulating films are provided in the noncontact part of the source/drain regions.

13. The semiconductor device according to claim 10, wherein contact holes are formed so as to partially overlap with the top of the buried insulating films.

14. The semiconductor device according to claim 10, wherein the buried insulating films have reached a BOX layer.

15. The semiconductor device according to claim 10, wherein the depth of the buried insulating films is two or more times that of the gate insulating film.

16. The semiconductor device according to claim 10, wherein the buried insulating films make no contact with the element isolating region.

17. The semiconductor device according to claim 10, wherein the buried insulating films make contact with the element isolating region in the channel width direction, but make no contact with the element isolating region in the channel length direction.

18. A semiconductor device manufacturing method comprising:
forming an element isolating region at the main surface of a substrate;
forming a gate insulating film and a gate electrode in an element region partitioned by the element isolating region;
introducing impurities into the element region using the gate electrode as a part of a mask to form a source/a drain region; and
forming buried insulating films in each of the source/drain regions to apply compressional stress to a channel region by volume expansion.

19. The semiconductor device manufacturing method according to claim 18, wherein forming an element isolating region at the main surface of a substrate is forming an STI region at the main surface of a semiconductor substrate.

20. The semiconductor device manufacturing method according to claim 18, wherein forming an element isolating region at the main surface of a substrate is forming an element isolating region in a silicon region of an SOI substrate to partition the silicon region to form an island-shaped silicon region.
